(19) United States
(12) Patent Application Publication
(10) Pub. No.: US 2013/0200768 A1
(43) Pub. Date: Aug. 8, 2013

(54) WATERPROOF STRUCTURE FOR ELECTRONIC DEVICE

(71) Applicant: SANYO Electric Co., Ltd., Osaka (JP)

(72) Inventors: Shigeki Miura, Ikoma-shi (JP); Kenichiro Koshino, Higashiosaka-shi (JP); Takashi Fujihata, Daito-shi (JP)

(73) Assignee: SANYO ELECTRIC CO., LTD., Osaka (JP)

(21) Appl. No.: 13/757,053

(22) Filed: Feb. 1, 2013

(30) Foreign Application Priority Data
Feb. 2, 2012 (JP) 2012-020429

(51) Int. Cl. H05K 5/06; H05K 5/02

(52) U.S. Cl. CPC H05K 5/069; H05K 5/0239
USPC 312/296

(57) ABSTRACT

A waterproof structure for an electronic device according to the present invention is provided with a seat formed around the opening of a casing and a packing member fixed to a back surface of a cover, the packing member being brought into tight contact with a seat when the cover is closed. A projection annularly extending and surrounding the opening is formed at the seat of the casing. The packing member includes: a base; a protrusion formed at a surface of the base, the projection being to be brought into press-contact over an entire length of the protrusion when the cover is closed; and a peripheral rib formed at the surface of the base in such a manner as to surround the protrusion, the peripheral rib being to be brought into press-contact with the seat of the casing when the cover is closed.

The present application claims priority to Japanese Patent Application No. 2012-020429. The entirety of Japanese Patent Application No. 2012-020429 is incorporated by reference herein.

### BACKGROUND OF THE INVENTION

1. Field of the Invention

The present invention relates to a waterproof structure for an electronic device such as a digital camera.

2. Description of the Related Art

In an electronic device such as a digital camera in the related art, a cover has been openably fixed to a casing in such a manner as to cover the opening of a jack for a USB connector or the like.

In an electronic device in which a cover is openably fixed with respect to the opening of a casing, an annular waterproof packing for surrounding the opening is disposed at a back surface of the cover in the state in which the cover is closed, so as to waterproof the casing.

When the cover is closed in such an electronic device, the waterproof packing is held between the casing and the cover under pressure, thereby achieving waterproofness.

However, in an electronic device, in which a user is supposed to open or close a cover, the cover is locked at a closure position via a locking structure such as a hook mechanism without using a tightening structure such as a screw in order to easily open or close the cover. Therefore, a waterproof packing need be held under a relatively small pressure in the state in which the cover is locked at the closure position.

Consequently, waterproof performance that the waterproof packing should exhibit is less than that in a structure for locking a cover at a closure position via a tightening structure such as a screw. Thus, it may raise a possibility of water intrusion into a casing.

### SUMMARY OF THE INVENTION

In view of the problem experienced by the related art, an object of the present invention is to provide a waterproof structure for an electronic device capable of achieving a higher waterproof performance than that in the related art.

An electronic device according to the present invention is provided with a cover which opens or closes an opening formed at a casing. A waterproof structure includes: a seat which is formed around the opening of the casing; and a packing member which is fixed to a back surface of the cover, the packing member which is brought into tight contact with the seat when the cover is closed.

A projection annularly extending and surrounding the opening is formed at the seat of the casing. The packing member includes: a base which is set at the back surface of the cover; a protrusion which is formed at a surface of the base, the projection which is brought into press-contact over an entire length of the protrusion when the cover is closed; and a peripheral rib which is formed at the surface of the base in such a manner as to surround the protrusion, the peripheral rib which is brought into press-contact with the seat of the casing when the cover is closed.

### BRIEF DESCRIPTION OF THE DRAWINGS

FIG. 1 is a perspective view showing the front side of a digital camera in an embodiment according to the present invention;

FIG. 2 is a perspective view showing the back side of the digital camera;

FIG. 3 is a perspective view showing the digital camera in the state in which a cover is opened;

FIG. 4 is a perspective view showing an enlarged essential parts in the state in which the cover is opened;

FIG. 5 is a cross-sectional view showing an enlarged essential parts in the state in which the cover is closed;

FIG. 6 is a cross-sectional view showing a waterproof structure in the state in which the cover is opened; and

FIG. 7 is a cross-sectional view showing a waterproof structure in the state in which the cover is closed.

### DETAILED DESCRIPTION OF THE PREFERRED EMBODIMENT

A description will be specifically given below of a digital camera in a preferred embodiment according to the present invention with reference to the attached drawings.

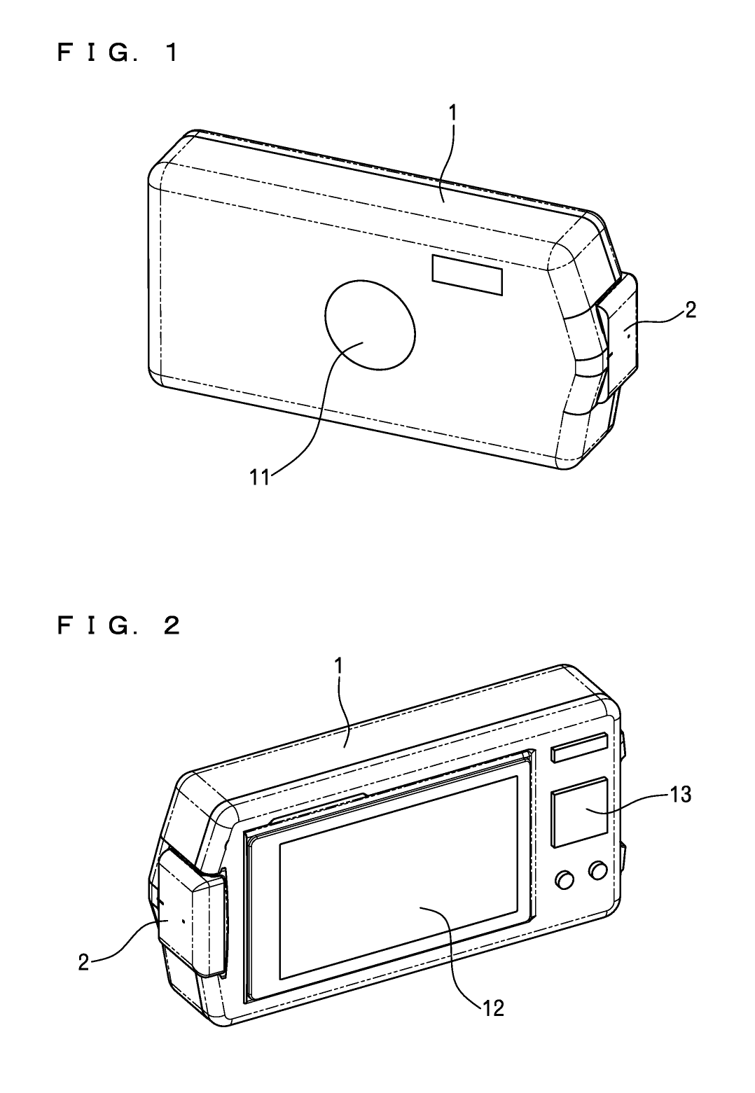

A digital camera in a preferred embodiment according to the present invention is provided with a shooting window 11 at the front surface of a casing 1, and further, is provided with a display 12 and an operating key 13 at the back surface of the casing 1, as shown in FIGS. 1 and 2.

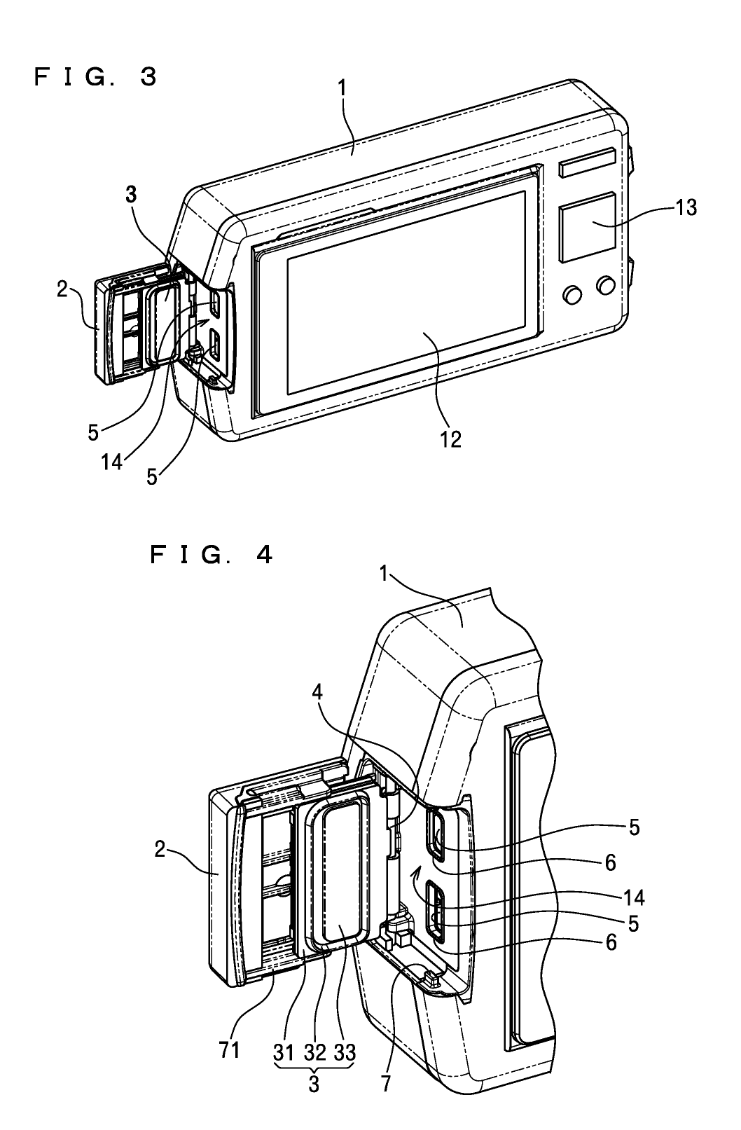

Moreover, a cover 2 is disposed at the side surface of the casing 1. When the cover 2 is opened, two openings 5 and 5 formed in the casing 1 are exposed to the outside, as shown in FIG. 3. In this manner, a USB plug can be connected to a USB jack (not shown) disposed at the back of each of the openings 5 and 5.

As shown in FIG. 4, the cover 2 is pivotally supported at the base end thereof by a pivot 4 at the casing 1, to be thus openably connected to the casing 1.

Additionally, a locking piece 7 is disposed at the casing 1, and further, a locking receiver 71 is formed at the cover 2, thus they constitute a locking mechanism for locking the cover 2 at a closure position. When the cover 2 is locked, the cover 2 is turned on the pivot 4 to be closed, and then, the cover 2 is allowed to slide toward the pivot 4, so that the locking piece 7 is engaged with the locking receiver 71.

At the back surface of the cover 2 is securely stuck a packing member 3 integrally molding an elastic material such as a silicone rubber.

In the meantime, a seat 14 being a surface of a member made of a synthetic resin is formed around the two openings 5 and 5 in the casing 1. At the seat 14 are formed annular projections 6 extending from the opening edges of the openings 5 in such a manner as to surround the openings 5.

The packing member 3 is provided with a flat plate-like base 31 to be set at the back surface of the cover 2, a protrusion 33 formed at the center surface of the base 31, and an annular peripheral rib 32 formed in such a manner as to surround the protrusion 33.

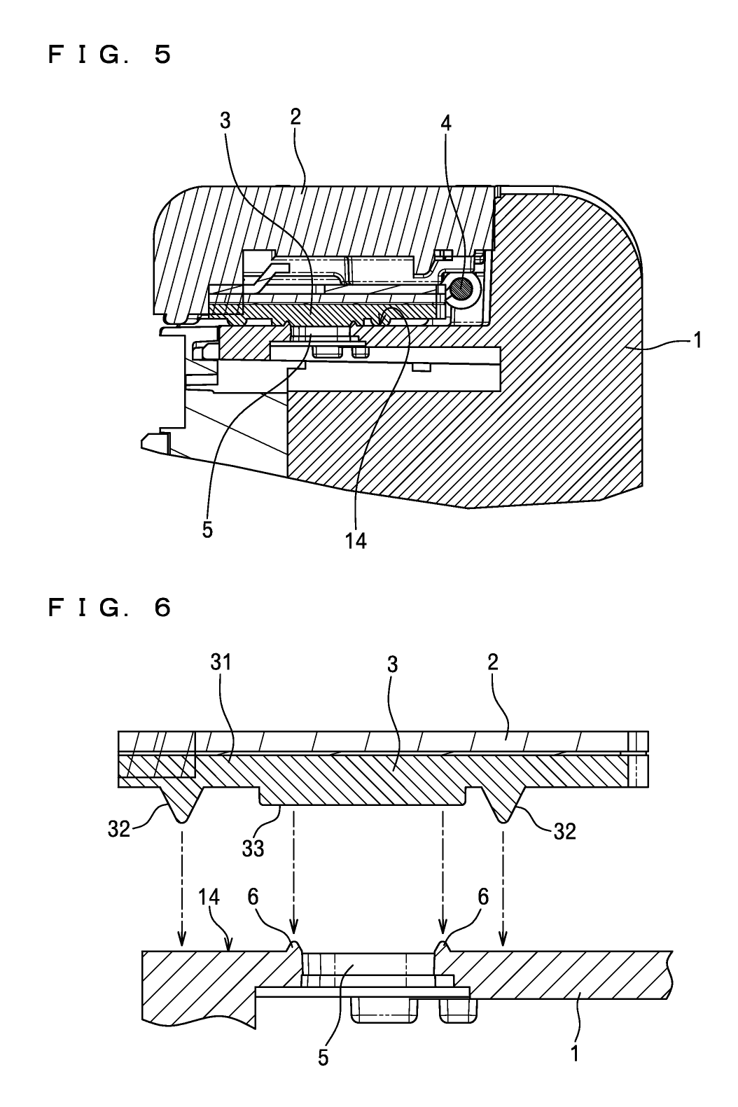

When the cover 2 is closed and locked with respect to the casing 1, the surface of the packing member 3 of the cover 2 is brought into press-contact with the seat 14 of the casing 1, so that the packing member 3 seals the openings 5, as shown in FIG. 5.

As shown in FIG. 6, the protrusion 33 of the packing member 3 protrudes in a flat shape such as to cover the openings 5 and the projections 6 of the casing 1, and further, the peripheral rib 32 is formed in an angle section so as to protrude toward the seat 14 of the casing 1.

Moreover, the projections 6 of the casing 1 are formed at the opening edges of the openings 5 in an angle section so as to project from the seat 14 toward the packing member 3.

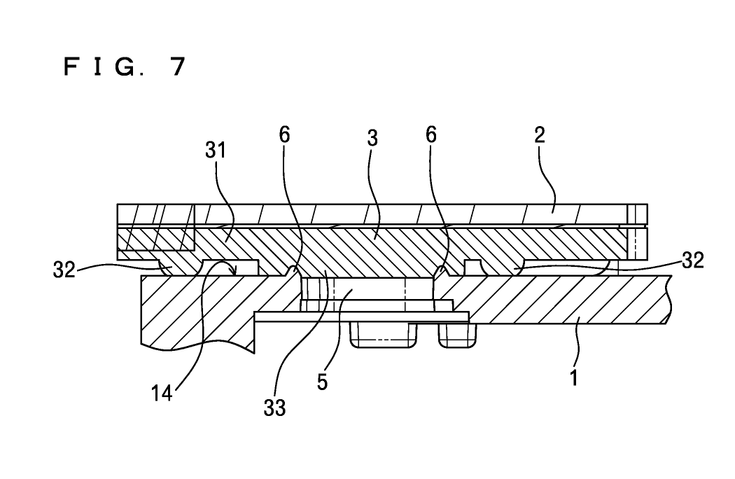

As shown in FIG. 7, when the cover 2 is closed and locked with respect to the casing 1, the projections 6 of the casing 1 are brought into press-contact with the protrusion 33 of the packing member 3, so that the protrusion 33 is elastically deformed in such a manner as to be recessed in conformity with the shape of the projections 6, and further, the peripheral rib 32 of the packing member 3 is brought into press-contact with the seat 14 of the casing 1 in such a manner as to be elastically deformed in the crush.

In this manner, an inner circumferential seal is defined between the projections 6 of the casing 1 and the protrusion 33 of the packing member 3, and further, an outer peripheral seal is defined between the seat 14 of the casing 1 and the peripheral rib 32 of the packing member 3.

Consequently, an annular sealed space is defined between a first seal and a second seal.

In this state, even if water will intrude from the outside, the outer peripheral seal first inhibits the water from intruding, and next, the inner circumferential seal inhibits the water from intruding. In other words, waterproofing can be dually achieved.

As a result, even if a little quantity of water intrudes through the outer peripheral seal because the cover 2 is held at the closure position under an insufficient pressure that acts on the packing member 3, the inner circumferential seal can inhibit the water from further intruding.

Even if a hair, for example, is held in either one of the first seal and the second seal to thus degrade the waterproof performance of the seal, the other seal exhibits a satisfactory sealability, thereby inhibiting water from intruding into the openings 5.

In addition, the projections 6 are formed in such a manner as to surround the openings 5 of the casing 1. Therefore, even if a water droplet adhering to the seat 14, for example, flows toward the openings 5 along the seat 14 when the cover 2 is opened, the projections 6 can hold back the flow of the water droplet, thus inhibiting the water from intruding into the openings 5.

Incidentally, the configuration of each of the constituent parts according to the present invention is not limited to that in the above-described preferred embodiment. Various changes can be made by those skilled in the art within the range not departing from the spirit of the present invention. For example, the protrusion 33 of the packing member 3 is not limited to the shape shown in the drawings, and therefore, it may be formed into an annular shape extending and surrounding the opening 5.

Alternatively, the peripheral rib 32 of the packing member 3 or the projection 6 of the casing 1 is not limited to the angle section, and therefore, it may be formed in a semi-circular section.

Moreover, the waterproof structure according to the present invention is not limited to the seal structure for the cover for covering the opening of a jack constituting a connector, and therefore, it may be embodied in a seal structure for a cover for covering the opening of a housing for a memory card or a battery, for example.

What is claimed is:

1. A waterproof structure for an electronic device provided with a cover which opens or closes an opening formed at a casing, the waterproof structure comprising:
a seat which is formed around the opening of the casing; and
a packing member which is fixed to a back surface of the cover, the packing member which is brought into tight contact with the seat when the cover is closed;
wherein a projection annularly extending and surrounding the opening is formed at the seat of the casing;
the packing member including:
a base which is set at the back surface of the cover;
a protrusion which is formed at a surface of the base, the projection which is to be brought into press-contact over an entire length of the protrusion when the cover is closed; and
a peripheral rib which is formed at the surface of the base so as to surround the protrusion, the peripheral rib which is to be brought into press-contact with the seat of the casing when the cover is closed.

2. The waterproof structure according to claim 1, wherein the cover is openably connected to the casing, and locked at a closure position by a locking mechanism interposed between the casing and the cover.

3. The waterproof structure according to claim 1, wherein the protrusion of the packing member is formed into such an outer shape as to cover the opening and projection of the casing.

4. The waterproof structure according to claim 2, wherein the protrusion of the packing member is formed into such an outer shape as to cover the opening and projection of the casing.

5. The waterproof structure according to claim 1, wherein the protrusion of the packing member is formed so as to have a flat surface.

6. The waterproof structure according to claim 2, wherein the protrusion of the packing member is formed so as to have a flat surface.

7. The waterproof structure according to claim 3, wherein the protrusion of the packing member is formed so as to have a flat surface.

8. The waterproof structure according to claim 4, wherein the protrusion of the packing member is formed so as to have a flat surface.

9. The waterproof structure according to claim 1, wherein both of the projection of the casing and the peripheral rib of the packing member are formed in an angle section.

10. The waterproof structure according to claim 2, wherein both of the projection of the casing and the peripheral rib of the packing member are formed in an angle section.

11. The waterproof structure according to claim 3, wherein both of the projection of the casing and the peripheral rib of the packing member are formed in an angle section.

12. The waterproof structure according to claim 4, wherein both of the projection of the casing and the peripheral rib of the packing member are formed in an angle section.

13. The waterproof structure according to claim 5, wherein both of the projection of the casing and the peripheral rib of the packing member are formed in an angle section.

14. The waterproof structure according to claim 6, wherein both of the projection of the casing and the peripheral rib of the packing member are formed in an angle section.

15. The waterproof structure according to claim 7, wherein both of the projection of the casing and the peripheral rib of the packing member are formed in an angle section.

16. The waterproof structure according to claim 8, wherein both of the projection of the casing and the peripheral rib of the packing member are formed in an angle section.
